(19) United States
(12) Patent Application Publication
(10) Pub. No.: US 2011/0199523 A1
(43) Pub. Date: Aug. 18, 2011

(54) IMAGING DEVICE

(76) Inventors: Koichi Tanabe, Kyoto-fu (JP); Toshinori Yoshimuta, Osaka-fu (JP); Susumu Adachi, Osaka (JP)

(21) Appl. No.: 13/124,099

(22) PCT Filed: Oct. 15, 2008
(86) PCT No.: PCT/JP2008/068666

§ 371 Date: Apr. 13, 2011

(51) Int. Cl. H04N 5/335

(52) U.S. Cl. 348/300; 348/311; 348/E05.091

(57) ABSTRACT

Conventional reset ability is fixed of resetting an amplifier in a charge-to-voltage conversion amplifier. According to an imaging device of this invention, reset ability may be switched. For this purpose, a reset ability-switching function is provided for switching power consumption of the amplifier as reset ability of resetting an amplifier in the charge-to-voltage conversion amplifier, which may realize free switching of the power consumption as the reset ability and adaptability to various types of charge-to-voltage conversion. Accordingly, heat generation may be suppressed by switching power consumption to the lower one in the case where heat generation possibly increases.

### TECHNICAL FIELD

This invention relates to an imaging device for use in the medical, industrial, nuclear and other fields.

### BACKGROUND ART

An imaging device for obtaining an image in accordance with charge information will be described by way of example where X-rays enter for conversion to charge information. The imaging device has an X-ray conversion layer of X-ray sensitive type. The X-ray conversion layer converts incident X-rays into carriers (charge information.) Amorphous selenium (a-Se) film is used for the X-ray conversion layer.

Moreover, the imaging device has a circuit for storing and reading out carriers converted in the X-ray conversion layer. As shown in FIG. 11, the circuit is formed of two or more gate lines G and data lines D arranged two dimensionally. The circuit also has capacitors Ca for storing carriers and thin film transistors (TFT) Tr for reading out carriers stored in the capacitors Ca through switching ON/OFF arranged two-dimensionally. The gate line G controls switching ON/OFF of each thin film transistor Tr, and is connected electrically to each gate of the thin film transistors Tr. The data line D is electrically connected to a readout side of the thin-film transistors Tr.

For instance, as shown in FIG. 11, a control sequence is as follows in a case where the gate line G has ten gate lines G1 to G10 and the data line D has ten data lines D1 to D10. Firstly, X-rays enter to generate carriers. The carriers are stored in the capacitors Ca. A gate line G1 is selected from a gate drive circuit 101, and each thin film transistor Tr is selected and specified that is connected to the selected gate line G1. The stored carriers are read out from the capacitor Ca connected to each selected and specified thin-film transistor Tr. The data lines D1 to D10 are read out in this order. Next, a gate line G2 is selected from the gate drive circuit 101. Likewise, the stored carriers are read out from the capacitors Ca connected to the selected gate line G2 and each thin film transistor Tr. The data lines D1 to D10 are read out in this order. The other gate lines G are likewise selected in order, whereby two-dimensional carriers are read out. Each carrier read out is amplified while being converted to a voltage with a charge-to-voltage converting amplifier. Then, it is converted from an analog value into a digital value by an A/D converter. In accordance with the carriers having the converted digital value, a two-dimensional image may be acquired. Here, as shown in FIG. 11, the charge-to-voltage amplifier and the A/D converter are installed on a circuit board 102.

As shown in FIG. 4(b), a readout interval as a time interval for reading out carriers in one gate line G is determined from amplifier reset time, gate ON time of the thin film transistor, output hold time of the amplifier (a sample hold is ON), conversion time for A/D conversion, and the like. Here, letting time for reading out every frame rate be “a readout period”, the period is of a readout interval by 10 (ten gate lines G1 to G10), as shown in FIG. 4(a). In addition, a frame rate is a time interval between frame synchronization signals. Timing of outputting a frame (i.e., frame reading) representing an image unit is controlled in synchronization with the frame synchronization signals. That is, carriers start to be read out in the frame synchronization signals having a constant period after a fixed time elapsed from the synchronized signals (in FIG. 4, a fixation time of “0”) (see, for example, Patent Document 1.) In FIG. 4, the above readout interval also corresponds to a charge-to-voltage conversion period by the charge-to-voltage conversion amplifier. Here, let a period from completion of readout to start-up of next readout be a “blank period.” X-rays are applied during the blank period to enter into the X-ray conversion layer. Here, as shown in FIG. 4, let a period from completion of applying (incidence) X-rays to the next frame synchronization signal be a.

The amplifier has fixed reset ability on conversion capacity for converting charges into voltages (charge-to-voltage conversion.) A shortest reset dwell time is determined in accordance with the highest imaging speed required for a system (i.e., the lowest frame rate, herein an imaging speed is the reciprocal of the frame rate.) The amplifier operates having reset ability with the reset dwell time.

[Patent Document 1]
Japanese Patent Publication 2006-304211 (Pages 7 to 9, FIG. 4)

### DISCLOSURE OF THE INVENTION

### Problem to be Solved by the Invention

However, there arises a problem that high power consumption is needed where the amplifier conventionally operates with the reset ability in accordance with the highest imaging speed (the lowest frame rate.) Accordingly, the system produces a larger amount of heat. Moreover, another problem arises that an electric power source itself increases in size for supplying electric powers to the system.

As mentioned above, amorphous selenium (a-Se) is often used for the X-ray conversion layer. It is known that the material is poor heat-resistance and is crystallized at 40° C. Accordingly, heat generation due to increased power consumption may causes a significant problem. In order to avoid such problem, it is necessary to take measures against heat dissipation, such as attachment of a heat pipe or a fan, etc. In such case, the dimension is extremely larger and the weight increases. In addition, the attachment is limited in position.

This invention has been made regarding the state of the art noted above, and its object is to provide an imaging device having adaptability to various types of charge-to-voltage conversion.

### Means for Solving the Problem

This invention is constituted as stated below to achieve the above object. An imaging device of one embodiment includes a conversion layer for converting information on light or radiation into charge information through incidence of the light or the radiation; a storage and readout circuit for storing and reading out the charge information converted in the conversion layer; and a charge-to-voltage conversion circuit for converting into voltage information the charge information read out in the storage and readout circuit for acquiring an image in accordance with the voltage information converted in the charge-to-voltage conversion circuit. The imaging device includes a reset ability-switching device for switching reset ability of resetting an amplifier in the charge-to-voltage conversion circuit. The reset ability is power consumption of the amplifier, and the reset ability-switching device switches power consumption of the amplifier.

The conventional reset ability is fixed of resetting an amplifier in the charge-to-voltage conversion circuit. According to the imaging device of one embodiment, the reset ability may be switched. For this purpose, the reset ability-switching device is provided for switching reset ability, which achieves free switching of the reset ability and adaptability to various types of charge-to-voltage conversion.

The reset ability is power consumption of the amplifier. In one embodiment mentioned above, the reset ability-switching device switches power consumption of the amplifier. Accordingly, heat generation may be suppressed by switching power consumption to the lower one in the case where heat generation possibly increases. As a result, an electric power source itself for supplying electric powers to the system may be reduced in size. Moreover, suppression of heat generation results in reduction in size or no need of a heat dissipation device.

An imaging device of another embodiment includes a conversion layer for converting information on light or radiation into charge information through incidence of the light or the radiation; a storage and readout circuit for storing and reading out the charge information converted in the conversion layer; and a charge-to-voltage conversion circuit for converting into voltage information the charge information read out in the storage and readout circuit for acquiring an image in accordance with the voltage information converted in the charge-to-voltage conversion circuit. The imaging device includes a reset ability-switching device for switching reset ability of resetting an amplifier in the charge-to-voltage conversion circuit. The image device further includes a thermometry device for determining a temperature in the conversion layer or the storage and readout circuit. Here, when the thermometry device determines a temperature of a given value or more, the reset ability-switching device preferably switches reset ability. The conventional reset ability is fixed of resetting an amplifier in the charge-to-voltage conversion circuit. According to the imaging device of another latter embodiment, the reset ability may be switched, which is similar to one former embodiment. For this purpose, the reset ability-switching device is provided for switching reset ability, which achieves free switching of the reset ability and adaptability to various types of charge-to-voltage conversion.

Specially, where the reset ability corresponds to power consumption of the amplifier as mentioned above, the reset ability-switching device performs switching as follows. That is, the reset ability-switching device switches power consumption of the amplifier. In addition, the reset ability-switching device switches power consumption to the lower one when the thermometry device determines a temperature of a given value or more, and switches power consumption to the higher one when the thermometry device determines a temperature lower than a given value. Accordingly, heat generation may be suppressed by switching power consumption to the lower one in the case where heat generation possibly increases in the conversion layer or the storage and readout circuit due to an increased temperature higher than a given value.

Moreover, where the reset ability corresponds to the power consumption of the amplifier as mentioned above, the following configuration may also be adopted. That is, a frame rate-switching device is provided for switching a time length of a frame rate representing a frame period as an image unit. The reset ability-switching device switches power consumption of the amplifier to the lower one in the case where the frame rate-switching device increases the frame rate, and switches power consumption of the amplifier to the higher one in the case where the frame rate-switching device reduces the frame rate. Conventionally, a reset dwell time is set in accordance with the lowest frame rate. Here, the reset dwell time is fixed. Consequently, the reset dwell time in a high frame rate is equal to that in the lowest frame rate. The constant shorter reset dwell time causes constant higher power consumption. In contrast to the former, the reset dwell time is set longer by an increased amount of the frame rate in the case where the frame rate increases, which leads to switching of power consumption of the amplifier to the lower one upon increasing of the frame rate. As above, heat generation may be suppressed by switching power consumption of the amplifier to the lower one in the case where the frame rate increases.

Power consumption is switched to the lower one when the thermometry device determines a temperature of a given value or more, and is switched to the higher one when the thermometry device determines a temperature lower than a given value. In such case, the reset ability-switching device may switch power consumption of the amplifier depending not on the time length of the frame rate but on the determination temperature by the thermometry device.

### Effect of the Invention

According to the imaging device of this invention (the former and latter embodiments), provision of the reset ability-switching device for switching reset ability of resetting the amplifier in the charge-to-voltage conversion circuit may realize free switching of the reset ability and adaptability to various types of charge-to-voltage conversion. Moreover, in one former embodiment, the reset ability-switching device switches power consumption of the amplifier. Accordingly, heat generation may be suppressed by switching power consumption to the lower one in the case where heat generation possibly increases. As a result, an electric power source itself for supplying electric powers to the system may be reduced in size. Moreover, suppression of heat generation results in reduction in size or no need of a heat dissipation device.

### BRIEF DESCRIPTION OF THE DRAWINGS

FIG. 1 is a schematic block diagram of X-ray apparatus according to Embodiment 1.

FIG. 2 is a schematic sectional view around an X-ray conversion layer of the X-ray apparatus.

FIG. 3 is a circuit diagram around a charge-to-voltage conversion amplifier and an A/D converter of the X-ray apparatus.

FIG. 4(a) is a timing chart of read-out intervals in a high-speed frame rate (animation.) FIG. 4(b) is a subdivided timing chart of the readout intervals in the high-speed frame rate (animation.)

FIG. 5 (a) is a timing chart of readout intervals in a low-speed frame rate (single radiography.) FIG. 5(b) is a subdivided timing chart of the readout intervals in the low-speed frame rate (single radiography.)

FIG. 6 is a subdivided timing chart of readout intervals having a high-speed frame rate (animation) and a low-speed frame rate (single radiography) arranged in temporal succession. FIG. 6(a) is in the high-speed frame rate (animation), and FIG. 6(b) in the low-speed frame rate (single radiography.)

FIG. 7 is a schematic view of a current switching circuit for switching power consumption of an amplifier.

FIG. 8 is a graph schematically showing a relationship of reset ability, a reset dwell time, and power consumption of the amplifier.

FIG. 9 is a schematic block diagram of X-ray apparatus according to Embodiment 2.

FIG. 10(a) is a schematic sectional view having a detection element circuit provided with a temperature sensor. FIG. 10(b) is a schematic sectional view having an X-ray conversion layer provided with a temperature sensor.

FIG. 11 is a schematic block diagram of conventional X-ray apparatus.

### DESCRIPTION OF REFERENCES

2 . . . detection element circuit
23 . . . X-Ray conversion layer
6 . . . controller
3 . . . charge-to-voltage conversion amplifier
31 . . . amplifier
10 . . . temperature sensor

### Embodiment 1

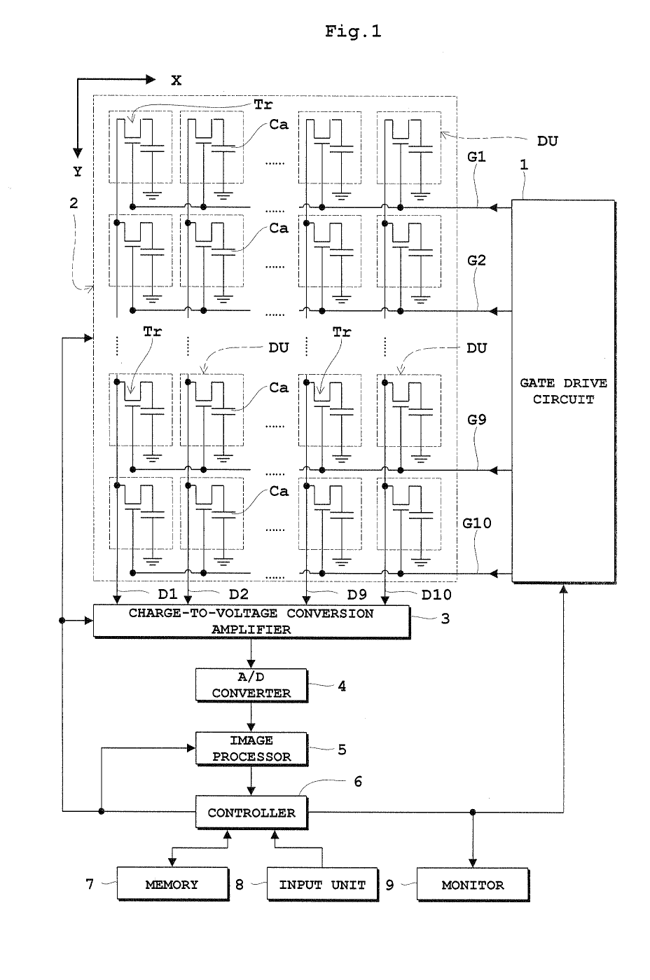

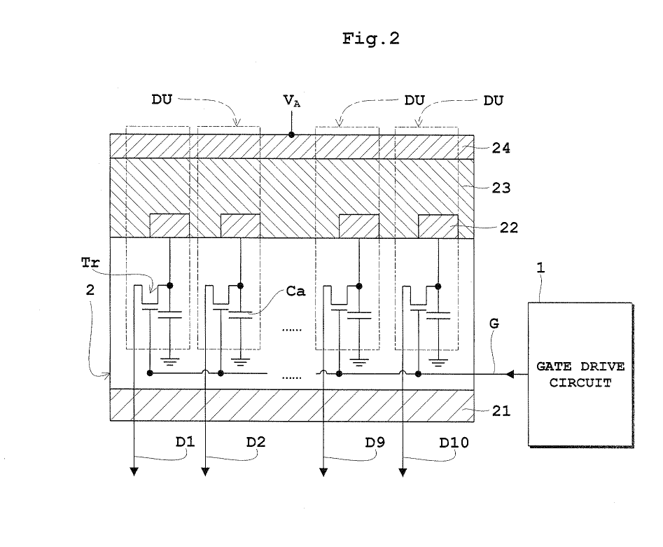

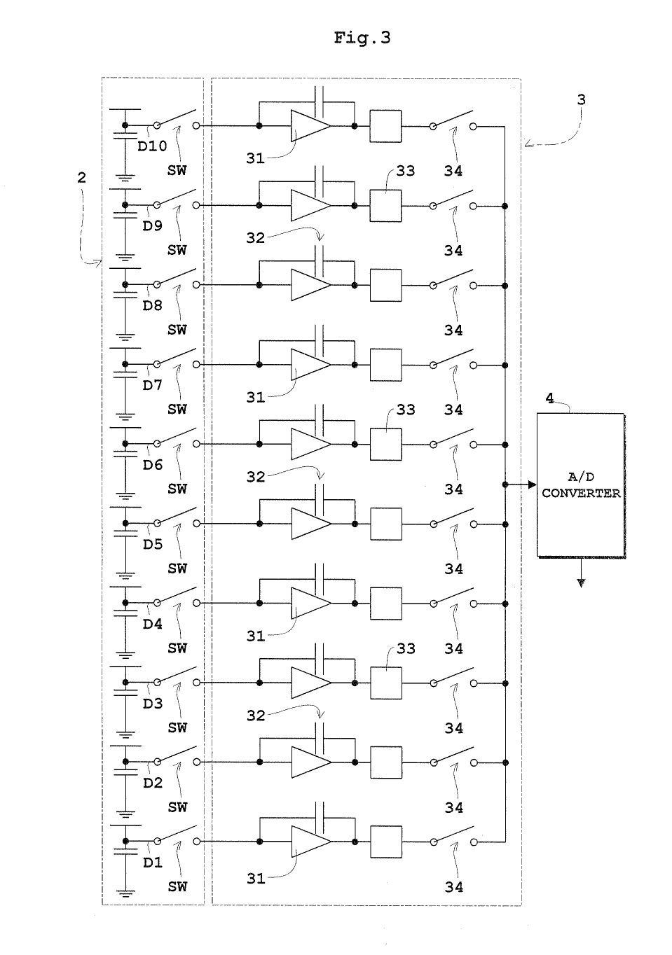

Embodiment 1 of this invention will be described in detail hereinafter with reference to the drawings. FIG. 1 is a schematic block diagram of X-ray apparatus according to Embodiment 1. FIG. 2 is a schematic sectional view around an X-ray conversion layer of the X-ray apparatus. FIG. 3 is a circuit diagram around a charge-to-voltage conversion amplifier and an A/D converter of the X-ray apparatus. Embodiment 1, and also Embodiment 2 to follow, will be described, taking X-rays as an example of incident radiation, and X-ray apparatus as an example of the imaging device.

X-ray apparatus according to Embodiment 1, and also Embodiment 2 to follow, irradiates a subject with X-rays for imaging. Specifically, an image of X-rays transmitting through the subject is projected on an X-ray conversion layer (here in Embodiment 1, an amorphous selenium film.) Carriers (charge information) proportional to density of the image are generated in the layer, whereby the X-ray image is converted into carriers.

As shown in FIG. 1, the X-ray apparatus includes a gate drive circuit 1 for selecting a gate line G mentioned later; a detection element circuit 2 for detecting X-rays through storing and reading out carriers converted in an X-ray conversion layer 23 (see FIG. 2); a charge-to-voltage conversion amplifier 3 for amplifying a carrier read out in the detection element circuit 2 and converted into voltage; an A/D converter 4 for converting the voltage amplified with the charge-to-voltage conversion amplifier 3 from an analog value into a digital value; an image processor 5 for acquiring an image through signal processing to the voltage having a converted digital value by the A/D converter 4; a controller 6 for controlling en bloc the circuits 1 and 2, the charge-to-voltage conversion amplifier 3, the A/D converter 4, the image processor 5, a memory 7 and monitor 9, mentioned later; a memory 7 for memorizing processed images; an input unit 8 for inputting settings; and a monitor 9 for displaying the processed images and so on. Information on such as a carrier and an image corresponds to image information with respect to an image herein in this specification. The X-ray conversion layer 23 corresponds to the conversion layer in this invention. The detection element circuit 2 corresponds to the storage and readout circuit in this invention. The charge-to-voltage amplifier 3 corresponds to the charge-to-voltage conversion circuit in this invention.

The gate drive circuit 1 is electrically connected to two or more gate lines G. Voltage is applied to each gate line G from the gate drive circuit 1, whereby a thin film transistor (TFT) Tr mentioned later is turned ON and readout starts of carriers stored in a capacitor Ca mentioned later. Voltage to each gate line G stops (voltage is set to −10V), whereby a thin film transistor Tr is turned OFF and readout of carriers is intercepted. Here, the thin film transistor Tr may be configured such that application of voltage to each gate line G leads to turning OFF of the thin film transistor Tr and interception of readout of carriers and that stopping of voltage to each gate line G leads to turning ON of the thin film transistor Tr and start of readout of carriers.

The detection element circuit 2 is formed of two or more gate lines G and data lines D arranged two dimensionally. The detection element circuit 2 also has capacitors Ca for storing carriers and thin film transistors (TFT) Tr for reading out carriers stored in the capacitors Ca through switching ON/OFF that are arranged two-dimensionally. The gate line G controls switching ON/OFF of each thin film transistor Tr, and is connected electrically to each gate of the thin film transistors Tr. The data line D is electrically connected to a readout side of the thin-film transistors Tr.

Here, for expediency of explanation, it is assumed that 10 by 10 thin film transistors Tr and capacitors Ca in rows and columns are formed in a two-dimensional matrix array in Embodiment 1 and also in Embodiment 2 to follow. That is, the gate line G has ten gate lines G1 to G10 and the data line D has ten data lines D1 to D10. Each of the gate lines G1 to G10 is connected to each gate of the ten thin film transistors Tr arranged parallel in an X-direction in FIG. 1. Each of the data lines D1 to D10 is connected to each readout side of the ten thin film transistors Tr arranged parallel in a Y-direction in FIG. 1. The capacitors Ca are electrically connected to a side opposite to a readout side of the thin-film transistors Tr. The thin film transistor Tr and the capacitor Ca correspond to one-to-one in number.

As shown in FIG. 2, the detection element circuit 2 has detection elements DU formed as a pattern on an insulating substrate 21 in a two-dimensional matrix array. Specifically, the insulating substrate 21 has the foregoing gate lines G1 to G10 and data lines D to D10 arranged on the surface thereof using a thin film formation technique with various vacuum evaporation methods, and a pattern technique with a photolithographic method. The thin film transistor Tr, the capacitor Ca, a carrier collecting electrode 22, the X-ray conversion layer 23, and a voltage application electrode 24 are laminated, in order, on the insulating substrate 21.

The X-ray conversion layer 23 is formed of an X-ray sensitive semiconductor thick film. In Embodiment 1 and also in Embodiment 2 to follow, the X-ray conversion layer 23 is formed of an amorphous selenium (a-Se) film. The X-ray conversion layer 23 converts information on X-rays into carriers as charge information through incidence of X-rays. Here, the X-ray conversion layer 23 is not particularly limited to amorphous selenium as long as it is an X-ray sensitive material that generates carriers through incidence of X-rays. Moreover, where imaging is performed through incidence of radiation other than X-rays (e.g. gamma-rays), a radiation-sensitive material may be used, instead of the X-ray conversion layer 23, that generates carriers through incidence of radiation. Moreover, where imaging is performed through incidence of light, a light-sensitive material may be used, instead of the X-ray conversion layer 23, that generates carriers through incidence of light.

As shown in FIG. 3, the charge-to voltage conversion amplifier 3 includes amplifiers 31 electrically connected to each data line D (D1 to D10 in FIG. 3); capacitors for amplifier 32 electrically connected to each data line D; sample holds 33 electrically connected in parallel to the amplifier 31 and the capacitor for amplifier 32 in every data line D; and switching elements 34 electrically connected to the sample holds 33 in every data line D. Moreover, the amplifier 31 is electrically connected via a switching element SW to an end of the data line D in the detection element circuit 2 in every data line D. The switching element SW is turned ON, and a carrier read out to the data line D is sent to the amplifier 31 and the capacitor for amplifier 32 in the charge-to-voltage conversion amplifier 3. The carrier is amplified that is sent and converted into voltage with the amplifier 31 and capacitor for amplifier 32. The sample hold 33 temporally stores the amplified voltage value for a given period. The switching element 34 is turned ON for sending the temporally stored voltage into the A/D converter 4. The A/D converter 4 converts the sent voltage from an analog value to a digital value.

Now returning to explanation on FIG. 1, the image processor 5 acquires an image through various signal processing to the voltage having a converted digital value by the A/D converter 4. The controller 6 controls en bloc the circuits 1 and 2, the charge-to-voltage conversion amplifier 3, the A/D converter 4, the image processor 5, a memory 7 and a monitor 9, mentioned later. In Embodiment 1 and also in Embodiment 2 to follow, the controller 6 further has functions of switching reset ability of resetting the amplifier 31 (power consumption of the amplifier 31 in Embodiment 1) in the charge-to-voltage conversion amplifier 3 (a reset ability switching function) and of switching time length of a frame rate representing a frame period as an image unit (a frame rate switching function.) The image processor 5 and the controller 6 are formed of a central processing unit (CPU) and the like. The controller 6 corresponds to the reset ability-switching device and the frame rate-switching device in this invention.

The memory 7 writes image information and memorizes it. The image information is read out from the memory 7 in accordance with readout instructions from the controller 6. The memory 7 is formed of a storage medium represented by such as a ROM (Read-only Memory), and RAM (Random-Access Memory.) Here, a RAM is used upon writing of image information. A ROM is used for reading out only the program on control sequence in the case where the controller 6 performs control sequence through readout of the program on control sequence. In Embodiment 1, the memory 7 memorizes a program on control sequence that a time length of the frame rate is switched, power consumption of the amplifier 31 is switched to the lower one in the case where the frame rate increases, and power consumption of the amplifier 31 is switched to the higher one in the case where the frame rate is reduced. The controller 6 performs control sequence through readout of the program.

The input section 8 is formed of a pointing device represented by such as a mouse, keyboard, joystick, trackball, and touch panel, or an input device such as a button, switch, and lever. Upon input setting to the input unit 8, input setting data is sent to the controller 6 for controlling the circuits 1 and 2, the charge-to-voltage conversion amplifier 3, the A/D converter 4, the image processor 5, the memory 7, the monitor 9, etc, in accordance with the input setting data.

Next, description will be given of control sequence of the X-ray apparatus according to Embodiment 1. X-rays to be detected enters with high bias voltage V_{A} (e.g., around several hundred volts to several ten kilovolts) being applied to a voltage application electrode 24.

X-rays enter to generate carriers in the X-ray conversion layer 23. The carriers are stored via the carrier collecting electrode 22 in the capacitors Ca as charge information. A target gate line G is selected in accordance with a scan signal (i.e., a gate driving signal) for reading out a signal (herein a carrier) from the gate drive circuit 1. Embodiment 1 has a description that the gate line G is selected one by one in order of the gate lines G1, G2, G3, . . . , G9, and G10. Moreover, the scan signal for reading out a signal from the gate drive circuit 1 is a signal for applying voltage (e.g., approximately 15V) to the gate line G.

A target date line G is selected from the gate drive circuit 1, and each thin film transistor Tr is selected and specified that is connected to the selected gate line G. Voltage is applied to the selected and specified gate of the thin film transistor Tr for turning the gate ON. The stored carriers are read out from the capacitor Ca connected to the data line D via the thin film transistors Tr selected and specified to be turned to ON state. That is, a detection element DU is selected and specified with respect to the selected gate line G. Thereafter, carriers stored in the capacitor Ca in the selected and specified detection element DU are read out to the data line D.

On the other hand, description will be given of the order of readout from each detection element DU with respect to the same selected and specified gate line G. That is, the data line D is to be selected one by one in order of the data lines D1 to D10. Specifically, the amplifier 31 in the charge-to-voltage conversion amplifier 3 is reset that is connected to the data line D. The thin film transistor Tr is turned to ON state (that is, the gate is ON.) Accordingly, carriers are read out to the data line D, and amplified while being converted into voltage with the amplifier 31 and the capacitor for amplifier 32 in the charge-to-voltage conversion amplifier 3.

That is, addressing is performed to each detection element DU in accordance with the scan signal for reading out a signal from the gate drive circuit 1 and selection of the amplifier 31 connected to the data line D.

Firstly, a gate line G1 is selected from the gate drive circuit 1, and a detection element DU is selected and specified with respect to the selected gate line G1. Then, carriers stored in the capacitor Ca in the selected and specified detection element DU are read out to the data lines in order of D1 to D10. Next, a gate line G2 is selected from the gate drive circuit 1. Likewise, a detection element DU is selected and specified with respect to the selected gate line G2. Then, carriers stored in the capacitor Ca in the selected and specified detection element Du are read out to the data lines in order of D1 to D10. The other gate lines G are likewise selected in order, whereby two-dimensional carriers are read out.

Each carrier read out is amplified while being converted to voltage with the amplifier 31 and the capacitor for amplifier 32. Then, the voltage is temporally stored in the sample hold 33 for conversion from an analog value into a digital value by the A/D converter 4. In accordance with the voltage having the converted digital value, the image processor 5 performs various signal processing to acquire a two-dimensional image. Image information represented by the acquired two-dimensional image, a carrier, etc., is written and stored in the memory 7 via the controller 6, and read out from the memory 7 as required. Moreover, the monitor 9 displays image information via the controller 6.

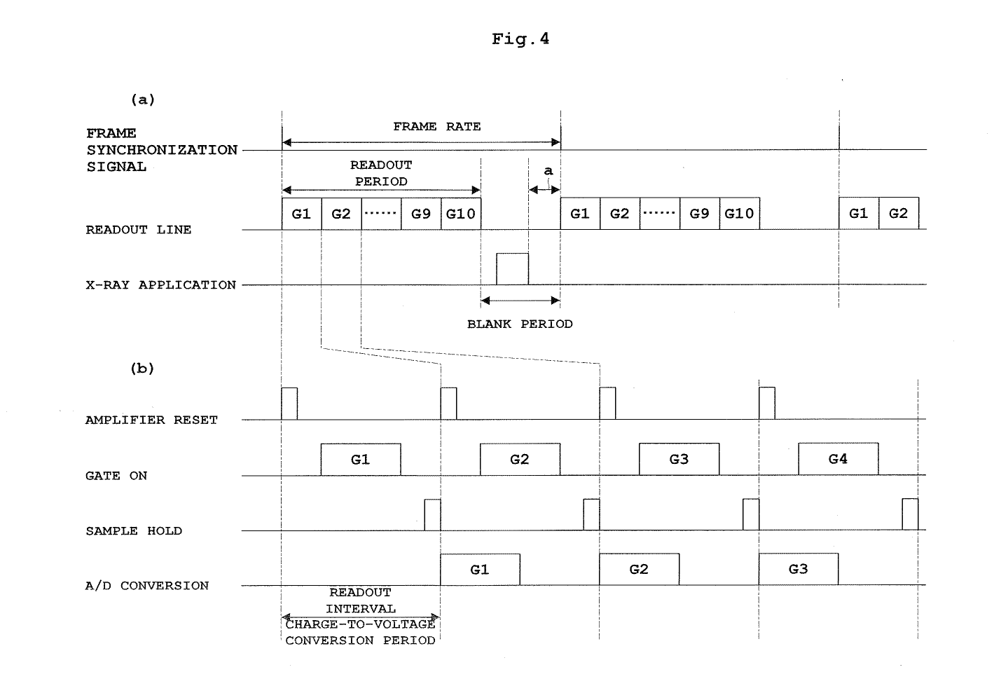

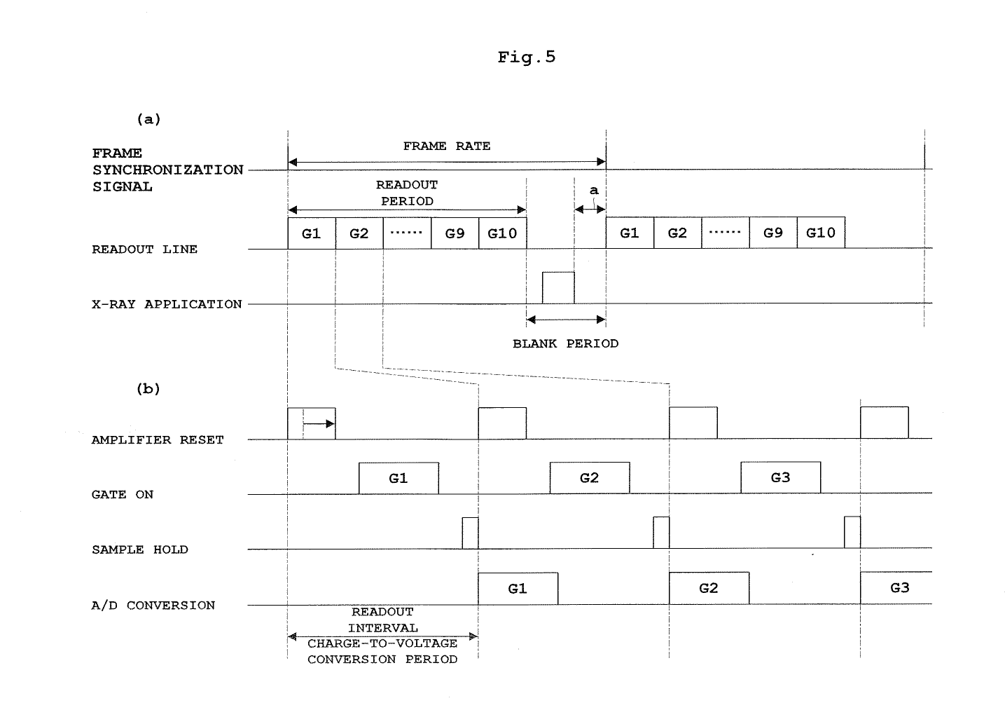

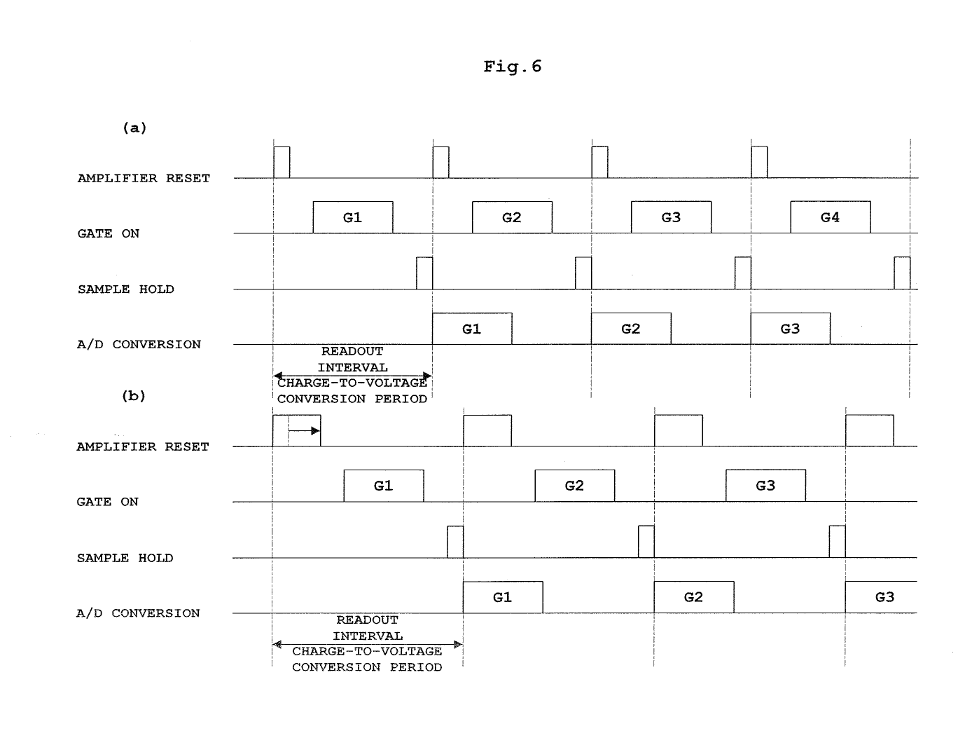

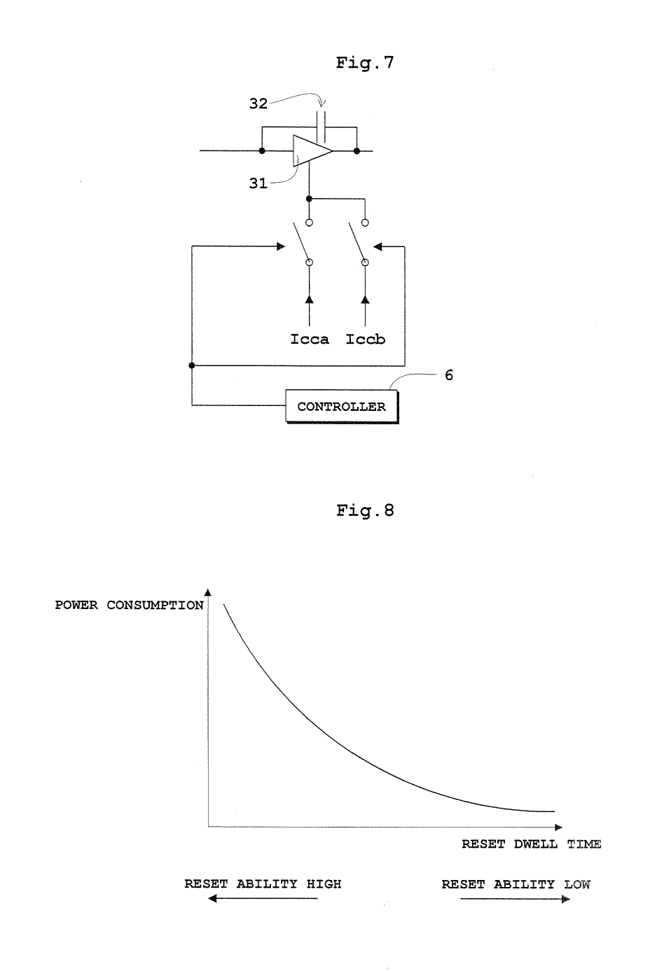

Next, description will be given of switching of power consumption of the amplifier 31 and switching of a time length of the frame rate with reference to FIGS. 4 to 8. FIG. 4(a) is a timing chart of readout intervals in a high-speed frame rate (animation.) FIG. 4(b) is a subdivided timing chart of the readout intervals in the high-speed frame rate (animation.) FIG. 5 (a) is a timing chart of readout intervals in a low-speed frame rate (single radiography.) FIG. 5(b) is a subdivided timing chart of the readout intervals in the low-speed frame rate (single radiography.) FIG. 6 is a subdivided timing chart of readout intervals having a high-speed frame rate (animation) and a low-speed frame rate (single radiography) arranged in temporal succession. FIG. 6(a) is in the high-speed frame rate (animation), and FIG. 6(b) in the low-speed frame rate (single radiography.) FIG. 7 is a schematic view of a current switching circuit for switching power consumption of an amplifier. FIG. 8 is a graph schematically showing a relationship of reset ability, a reset dwell time, and power consumption of the amplifier.

A readout interval is an interval of time to read carriers in one gate line G Herein, the readout interval is subdivided into timing charts as shown in FIGS. 4(b) and 5(b). The readout interval expresses an interval from starting of amplifier reset with the amplifier 31 in the gate line G to be selected to starting of amplifier reset with the amplifier 31 in the gate line G to be next selected.

Specifically, as shown in FIGS. 4(b) and 5(b), upon completion of amplifier reset, a gate line G is selected for turning the gate of the thin film transistor Tr to ON state. With this turning, carriers are read out from each detection element DU with respect to the gate line G. The gate of the thin film transistor Tr turns to OFF state, and thereafter the sample hold 33 indicating amplifier output hold is turned ON from starting of amplifier reset to stabilization of output of the amplifier 31, strictly speaking, after latency time for stabilizing amplifier output elapses as a time from turning OFF of the gate of the thin film transistor Tr to stabilization of output of the amplifier 31. The sample hold 33 is turned OFF and the switching element 34 is turned ON, and thereafter the A/D converter 4 is turned ON. As a result, an analog value is converted into a digital value.

FIG. 4(a) is a timing chart in a high-speed frame rate, and is suitable for animation that acquires images successively in a low frame rate (i.e., high radiography speed.) FIG. 5 (a) is a timing chart in a low-speed frame rate, and suitable for single radiography that acquires images in a single step in the low-speed frame rate (i.e., low radiography speed.) In Embodiment 1, as shown in FIG. 6(a), a time length of the frame rate is switched to be the shorter one as in the high-speed frame rate (animation.) After the high-speed frame rate (animation), a time length of the frame rate is switched to be the longer one as in the low-speed frame rate (single radiography.) Here, description will be given under assumption that the timing chart of FIG. 6(a) is temporally continued on that of FIG. 6(b), and timing chart of FIG. 6(b) follows immediately after that of FIG. 6(a).

In the high-speed frame rate (animation), the controller 6 (see FIG. 1) switches the readout interval to the shorted one, as shown in FIGS. 4(b) and 6(a). The readout intervals are reduced, and accordingly, all gate lines G1 to G10 has reduced readout intervals. As a result, (a time length of) the frame rate is reduced. On the other hand, in the low-speed frame rate (single radiography), the controller 6 (see FIG. 1) switches the readout interval to the longer one, as shown in FIGS. 5(b) and 6(b). The readout intervals increases, and accordingly, all gate lines G1 to G10 have increased readout intervals. As a result, (a time length of) the frame rate increases.

As is described in Background Art, the amplifier conventionally has fixed reset ability on conversion capacity. A shortest reset dwell time is determined by a system (the X-ray apparatus in Embodiment 1) in accordance with the lowest frame rate (i.e., high-speed frame rate: animation.) The amplifier operates with the shortest reset dwell time same as that in the lowest frame rate even when the time length of the frame rate is switched to the longer one. In Embodiment 1, the readout interval increases in the low-speed frame rate (single radiography.) Using this, as shown in FIGS. 5(b) and 6(b), the reset dwell time of the amplifier 31 (see the “amplifier reset” in FIGS. 5(b) and 6(b)) is set longer than that in the high-speed frame rate (animation.)

The amplifier 31 and the surrounding circuits in FIG. 3 are configured as in FIG. 7 for setting the reset dwell time variable. Specifically, current supplied to the amplifier 31 is conventionally fixed. The controller 6 switches to either current Icca or current Iccb, as shown in FIG. 7. Here, it is assumed that Icca>Iccb. Accordingly, the controller 6 switches so as to apply current Icca to the amplifier 31 for increasing power consumption and current Iccb to the amplifier 31 for reducing power consumption.

The amplifier 31 has a relationship of reset ability, a reset dwell time, and power consumption shown in FIG. 8. High reset ability results in reset in a short time. Low reset ability leads to a longer reset dwell time and reduced power consumption, whereas high reset ability leads to a shorter reset dwell time and increased power consumption. In other words, increased power consumption leads to a reduced reset dwell time, and reduced power consumption leads to an increased reset dwell time. In summary, supply of current Icca to the amplifier 31 leads to increased power consumption and a reduced reset dwell time, whereas supply of current Iccb to the amplifier 31 leads to reduced power consumption and an increased reset dwell time. As above, in the high-speed frame rate (animation), i.e., in the reduced frame rate, supply of current Icca to the amplifier 31 leads to switching of power consumption to the higher one for reducing the reset dwell time. In the low-speed frame rate (single radiography), i.e., in the increased frame rate, supply of the amplifier 31 to current Iccb leads to switching of power consumption to the lower one for increasing the reset dwell time.

The conventional reset ability is fixed of resetting the amplifier in the charge-to-voltage conversion amplifier. According to the X-ray apparatus in Embodiment 1, the reset ability may be switched. For this purpose, the controller 6 has the reset ability-switching function for switching reset ability of resetting the amplifier 31 in the charge-to-voltage conversion amplifier 3 (power consumption of the amplifier 31 in Embodiment 1), which may realize free switching of the reset ability (here, power consumption) and adaptability to various types of charge-to-voltage conversion.

In Embodiment 1, the reset ability corresponds to power consumption of the amplifier 31. In Embodiment 1, the reset ability-switching function switches power consumption of the amplifier 31. Accordingly, heat generation may be suppressed by switching power consumption to the lower one in the case where heat generation possibly increases. As a result, an electric power source itself for supplying electric powers to the system (the X-ray apparatus in Embodiment 1) may be reduced in size. Moreover, suppression of heat generation results in reduction in size or no need of a heat dissipation device.

Moreover, where the reset ability corresponds to power consumption of the amplifier 31 as in Embodiment 1, the following configuration may also be adopted. That is, a frame rate-switching function is provided for switching a time length of a frame rate representing a frame period as an image unit. The reset ability-switching function switches power consumption of the amplifier 31 to the lower one in the case where the frame rate-switching function increases the frame rate (in the low-speed frame rate: single radiography), and switches power consumption of the amplifier 31 to the higher one in the case where the frame rate-switching function reduces the frame rate (in the high-speed frame rate: animation.) Conventionally, a reset dwell time is set in accordance with the lowest frame rate. Here, the reset dwell time is fixed. Consequently, a reset dwell time in a high frame rate is equal to that in the lowest frame rate. The constant shorter reset dwell time causes constant higher power consumption. In contrast to the conventional former, a reset dwell time is set longer by an increased amount of the frame rate in the case where the frame rate increases, which leads to switching of power consumption of the amplifier 31 to the lower one upon increasing of the frame rate. As above, heat generation may be suppressed by switching power consumption of the amplifier 31 to the lower one in the case where the frame rate increases.

### Embodiment 2

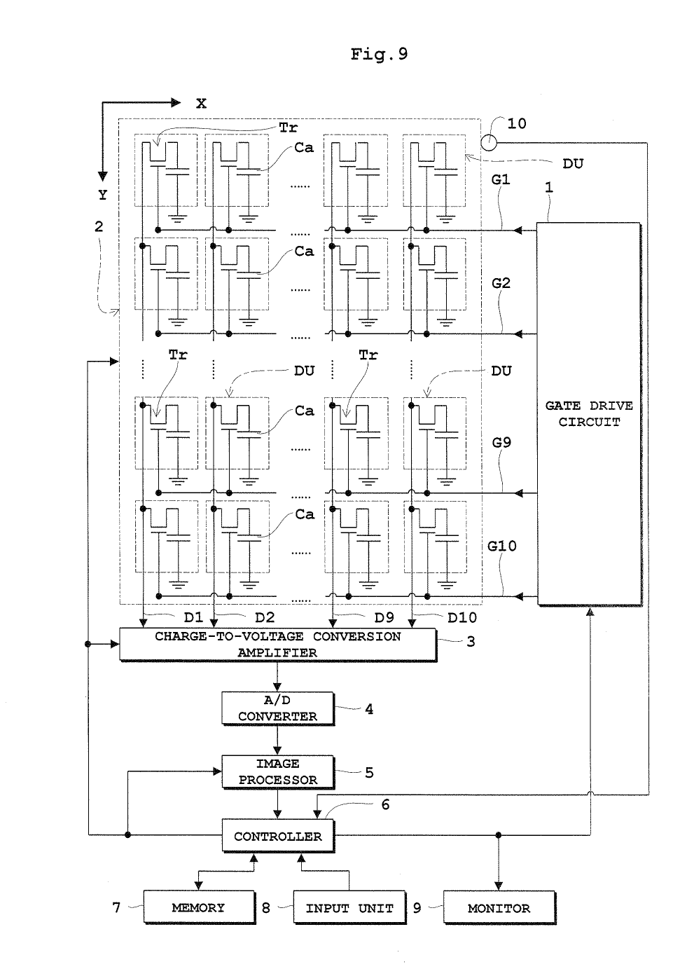

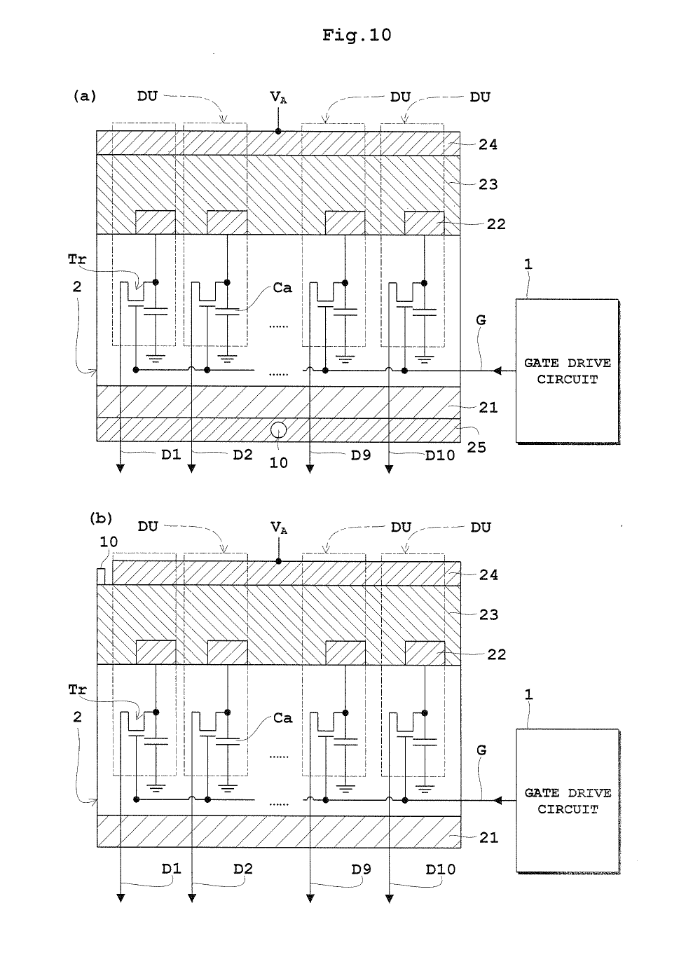

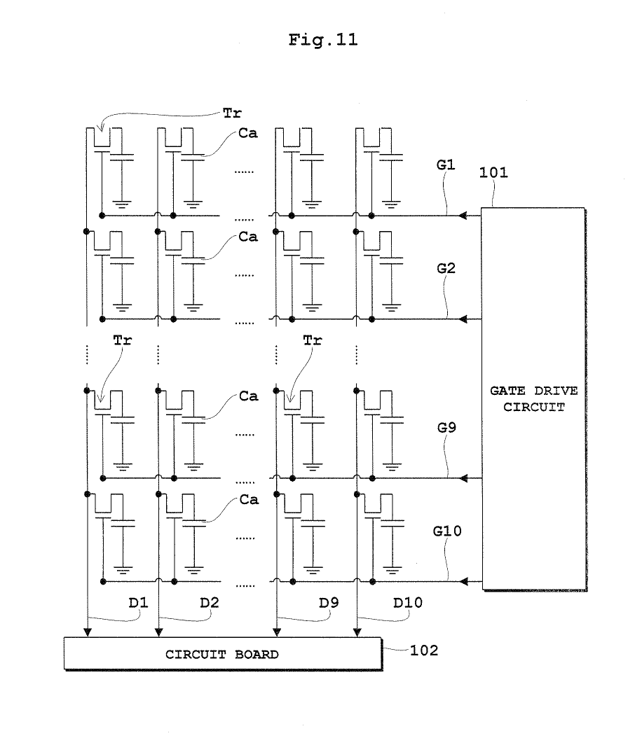

Next, Embodiment 2 of this invention will be described in detail hereinafter with reference to the drawings. FIG. 9 is a schematic block diagram of X-ray apparatus according to Embodiment 2. FIG. 10(a) is a schematic sectional view having a detection element circuit provided with a temperature sensor. FIG. 10(b) is a schematic sectional view having an X-ray conversion layer provided with a temperature sensor. The same elements as in Embodiment 1 are represented by the same numerals, and the description thereof is to be omitted.

X-ray apparatus according to Embodiment 2 includes a gate drive circuit 1, a detection element circuit 2, a charge-to-voltage conversion amplifier 3, an A/D converter 4, an image processor 5, a controller 6, a memory 7, an input unit 8, and a monitor 9, which is similar to the foregoing Embodiment 1. Beside, the X-ray apparatus in Embodiment 2 includes a temperature sensor 10 for determining a temperature of the X-ray conversion layer 23 (see FIG. 10) or the detection element circuit 2. The determination result by the temperature sensor 10 is sent to the controller 6. The temperature sensor 10 corresponds to the thermometry device in this invention.

As shown in FIG. 10(a), the temperature sensor 10 is provided in the detection element circuit 2 for determining a temperature of the detection element circuit 2. Specifically, a metal film 25 is laminated under an insulating substrate 25, the metal film 25 having the temperature sensor 10 embedded therein. Here, for example, aluminum (Al) is used for the metal film 25. Of course, an aspect of providing the temperature sensor 10 in the detection element circuit 2 is not limited to that in FIG. 10(a).

As shown in FIG. 10(b), the temperature sensor 10 is provided in the X-ray conversion layer 23 for determining a temperature of the X-ray conversion layer 23. Specifically, the temperature sensor 10 directly contacts to the X-ray conversion layer 23. Of course, an aspect of providing the temperature sensor 10 in the X-ray conversion layer 23 is not limited to that in FIG. 10(b).

As mentioned in “Problem to be Solved by the Invention”, where the X-ray conversion layer 23 is formed of amorphous selenium (a-Se) as in the foregoing Embodiment 1 and also in Embodiment 2 to follow, amorphous selenium is poor heat-resistance and is crystallized at 40° C. Accordingly, heat generation due to increased power consumption may causes a significant problem. Specifically, where amorphous selenium crystallizes due to increase of the temperature, a region to which no imaging is performed may be generated in the screen, or the sensor may be broken occasionally due to electric discharge of high bias voltage that is applied in the X-ray conversion layer, which may cause impossible radiography. In general, in such X-ray apparatus, dangers may be posed to a patient's life when imaging stops during treatment to a patient or imaging cannot be performed to an urgent patient. This may cause a significant problem.

Accordingly, Embodiment 2 includes the temperature sensor 10 as above. The determination result by the temperature sensor 10 is sent to the controller 6. The controller 6 has the reset ability-switching function of switching the reset ability (power consumption of the amplifier 31 in Embodiment 2) in the case where the temperature sensor 10 determines a temperature of a given value (e.g., 40° C.) or more.

Specially, where the reset ability corresponds to power consumption of the amplifier 31 as in Embodiment 2, the reset ability-switching function performs switching as follows. That is, the reset ability-switching function switches power consumption of the amplifier 31. In addition, the reset ability-switching function switches power consumption to the lower one when the temperature sensor 10 determines a temperature of a given value or more, and switches power consumption to the higher one when the temperature sensor 10 determines a temperature lower than a given value. Accordingly, heat generation may be suppressed by switching power consumption to the lower one in the case where heat generation possibly increases in the X-ray conversion layer 23 or the detection element circuit 2 due to an increased temperature higher than a given value.

Moreover, the foregoing Embodiment 1 and Embodiment 2 may be combined. Specifically, power consumption of the amplifier 31 may be switched to the lower one only in the case where the frame rate increases as in Embodiment 1 and the temperature sensor 10 determines a temperature of a given value of more as in Embodiment 2. Power consumption of the amplifier 31 may also be switched to the higher one only in the case where the frame rate is reduced as in Embodiment 1 and the temperature sensor 10 determines a temperature lower than a given value as in Embodiment 2.

Moreover, as in Embodiment 2, power consumption is switched to the lower one where the temperature sensor 10 determines a temperature of a given value or more and is switched to the higher one where the temperature sensor 10 determines a temperature lower than a given value. In such case, power consumption of the amplifier 31 may be switched depending not on the time length of the frame rate but on the determination temperature by the temperature sensor 10. Therefore, this invention is applicable where the frame rate is switched as in the foregoing Embodiment 1. This invention is also applicable where the frame rate is fixed. Here, power consumption is to be switched depending only on the determination result with the temperature sensor 10 where this invention is applied to any case.

Moreover, in the above case, switching is independent of the time length of the frame rate. Consequently, the reset dwell time is reduced where power consumption is switched to the higher one when the temperature sensor 10 determines a temperature lower than a given value, which leads to a problem that the amplifier 31 cannot be reset sufficiently. In addition, artifacts will be generated in a portion of an image where a constant dose or more of X-rays is applied. Embodiment 2, however, includes the temperature sensor 10 for acquiring images in an emergency such as failure in an air conditioner, etc. Accordingly, the artifacts mentioned above pose no problem in terms of emergent image acquisition. Consequently, images may be acquired without of crystallization amorphous selenium upon increasing an environmental temperature of the system (the X-ray apparatus in Embodiment 2) in emergencies, such as failure of the air conditioner, and without failure of the system.

This invention is not limited to the foregoing embodiment, but may be modified as follows.

(1) In each foregoing embodiment described above, the X-ray apparatus as in FIG. 1 has been described by way of example. This invention is also applicable to fluoroscopic apparatus mounted on a C-shaped arm, for example. This invention may be applied also to X-ray CT apparatus.

(2) In each foregoing embodiment described above, this invention is applied to a circuit for a “direct conversion type” detection element that converting incident radiation represented by X-rays into charge information in the X-ray conversion layer. This invention is also applicable to a circuit for an “indirect conversion type” detection element that converts incident radiation into light in the conversion layer such as a scintillator, and converting the light into charge information in a conversion layer made of a light-sensitive material.

(3) In each foregoing embodiment described above, the detection element circuit for detecting X-rays has been described by way of example. This invention is not limited to a particular type of detection element circuit for detecting radiation, but may for example be a detection element circuit for detecting gamma rays emitted from a patient dosed with radioisotope (RI), such as in ECT (Emission Computed Tomography) apparatus. Similarly, this invention is not limited to particular apparatus, but may be applied to any apparatus that performs imaging through incident radiation, as exemplified by the ECT apparatus mentioned above.

(4) In each foregoing embodiment described above, imaging through radiation represented by X-rays has been described by way of example. This invention is also applicable to an imaging device performing imaging through incident light.

(5) In the foregoing Embodiment 1, a case has been described by way of example where the high-speed frame rate (animation) or the low-speed frame rate (single radiography) is switched to two steps. Switching to three or more steps may of course be performed for minute control. For instance, switching to three steps of a high-speed frame rate, a medium-speed frame rate, and a low-speed frame rate may be performed. Power consumption of the amplifier 31 may be switched to the lower one upon increasing the frame rate (in the low-speed frame rate: radiography) relative to the medium-speed frame rate. Power consumption of the amplifier 31 may be switched to the higher one upon reducing the frame rate (in the high-speed frame rate: animation) relative to the medium-speed frame rate. Power consumption of the amplifier 31 may also be switched to the medium one in the medium-speed frame rate. Moreover, a mode with less power consumption may be provided for suppressing power consumption under radiography atmosphere.

(6) In the foregoing Embodiment 2, a case has been described by way of example where power consumption of the amplifier 31 is switched to two steps when the temperature sensor 10 determines a temperature of a given value (e.g., 40° C.) or more. Switching to three or more steps may of course be performed for minute control. For instance switching to three steps may be performed in which power consumption is switched to the lower one when the temperature sensor 10 determines a temperature of 20° C. or more, and switched to the further lower one when the temperature sensor 10 determines a temperature of 40° C. or more.

(7) In each foregoing embodiment, a case has been describe by way of example where power consumption of the amplifier 31 is switched to two steps of current Icca and current Iccb, as shown in FIG. 7. Switching to three or more steps may of course be performed for minute control. For instance, it is assumed that Icca>lccb>Iccc, and switching to three steps may be performed of applying to the amplifier 31 any of Icca, Iccb, and lccc.

(8) In each foregoing embodiment, switching of current Icc (Icca, Ica)) is controlled for control of power consumption of the amplifier 31. Power consumption of the amplifier 31 may also be controlled through control of switching of voltage Vcc or resistance.

1. An imaging device comprising a conversion layer for converting information on light or radiation into charge information through incidence of the light or the radiation, a storage and readout circuit for storing and reading out the charge information converted in the conversion layer, and a charge-to-voltage conversion circuit for converting into voltage information the charge information read out in the storage and readout circuit, for acquiring an image in accordance with the voltage information converted in the charge-to-voltage conversion circuit,
the imaging device further comprising a reset ability-switching device for switching reset ability of resetting an amplifier in the charge-to-voltage conversion circuit, the reset ability being power consumption of the amplifier, and the reset ability-switching device switching power consumption of the amplifier.

2. (canceled)

3. An imaging device comprising a conversion layer for converting information on light or radiation into charge information through incidence of the light or the radiation, a storage and readout circuit for storing and reading out the charge information converted in the conversion layer, and a charge-to-voltage conversion circuit, for converting into voltage information the charge information read out in the storage and readout circuit for acquiring an image in accordance with the voltage information converted in the charge-to-voltage conversion circuit, the imaging device further comprising a reset ability-switching device for switching reset ability of resetting an amplifier in the charge-to-voltage conversion circuit, and a thermometry device for determining a temperature in the conversion layer or the storage and readout circuit, the reset ability-switching device switching reset ability upon determination a temperature of a given value or more by the thermometry device.

4. The imaging device according to claim 3, wherein the reset ability is power consumption of the amplifier, and the reset ability-switching device switches power consumption of the amplifier, switches power consumption to the lower one when the thermometry device determines a temperature of a given value or more, and switches power consumption to the higher one when the thermometry device determines a temperature lower than a given value.

5. The imaging device according to claim 4, wherein a frame rate-switching device is provided for switching a time length of a frame rate representing a frame period as an image unit, the reset ability-switching device switching power consumption of the amplifier to the lower one in the case where the frame rate-switching device increases the frame rate, and switching power consumption of the amplifier to the higher one in the case where the frame rate-switching device reduces the frame rate.

6. The imaging device according to claim 4, wherein the reset ability-switching device switches power consumption of the amplifier depending not on a time length of a frame rate representing a frame period as an image unit but on the determination temperature by the thermometry device.

7. The imaging device according to claim 1, wherein a frame rate-switching device is provided for switching a time length of a frame rate representing a frame period as an image unit, the reset ability-switching device switching power consumption of the amplifier to the lower one in the case where the frame rate-switching device increases the frame rate, and switching power consumption of the amplifier to the higher one in the case where the frame rate-switching device reduces the frame rate.
